(19) United States
(12) Patent Application Publication
(10) Pub. No.: US 2025/0181785 A1
(43) Pub. Date: Jun. 5, 2025

(54) SYSTEMS AND METHODS FOR DETERMINING USE CASE-SPECIFIC ARCHITECTURE PATTERN AND TOOLS FOR APPLICATIONS

(71) Applicant: Capital One Services, LLC, McLean, VA (US)

(72) Inventor: Jacoby SMITH, Fredericksburg, VA (US)

(73) Assignee: Capital One Services, LLC, McLean, VA (US)

(21) Appl. No.: 18/529,160

(22) Filed: Dec. 5, 2023

(51) Int. Cl. G06F 30/13

(52) U.S. Cl. CPC G06F 30/13

(57) ABSTRACT

An architecture pattern and tools may be determined for an application. For instance, conversation data between a user and a virtual assistant associated with a use case for an application may be received from a user device, and a plurality of functions to serve the use case may be identified based on the conversation data. An architecture pattern may be determined for the application based on the plurality of functions, where the architecture pattern may indicate a plurality of tool types for performing the plurality of functions. For each tool type of the plurality of tool types, a particular tool may be determined, from a plurality of tools associated with the respective tool type, to perform a corresponding function from the plurality of functions based on the conversation data. The architecture pattern and the particular tool determined for each tool type may be provided to the user device for display.

### TECHNICAL FIELD

Various embodiments of this disclosure relate generally to techniques for determining architecture patterns and tools for applications, and, more particularly, to systems and methods for determining use case-specific architecture patterns and tools.

### BACKGROUND

When developing an application and/or modifying an existing application, a use case for the application may drive the type of architecture pattern and/or functional tools selected for implementation of the application to help ensure the use case is sufficiently served or fulfilled. Conventionally, a solutions and/or systems architect may obtain a use case, identify keywords from the use case, and manually select an architecture pattern and tools based on the keywords using their expert knowledge and experience. However, for any given architecture pattern, there are a large number of tools available from various different service providers for implementation, and new and/or updated tools are continuously becoming available on a frequent basis. Despite the wealth of available tools, each providing particular advantages or disadvantages (e.g., pros or cons) dependent on use case, it is common for a solutions and/or systems architect to select from a small number of tools that they are most familiar with. Additionally, despite the increase in agnostic tools, the tools selected are often specific to a same service provider (e.g., a service provider of the architecture corresponding to the architecture pattern).

The background description provided herein is for the purpose of generally presenting the context of the disclosure. Unless otherwise indicated herein, the materials described in this section are not prior art to the claims in this application and are not admitted to be prior art, or suggestions of the prior art, by inclusion in this section.

### SUMMARY OF THE DISCLOSURE

According to certain aspects of the disclosure, methods and systems are disclosed for determining architecture patterns and tools for applications. The methods and systems may include machine-learning based determinations of use case-specific architecture patterns and tools for applications.

In some aspects, methods for determining an architecture pattern and tools for an application may be described. An example method may include receiving, from a user device, conversation data between a user and a virtual assistant associated with a use case for an application, the conversation data indicating one or more optimization factors, and identifying a plurality of functions to serve the use case based on the conversation data. The example method may also include determining, using a first machine learning system, an architecture pattern for the application based on the plurality of functions, where the architecture pattern may indicate a plurality of tool types for performing the plurality of functions, and for each tool type of the plurality of tool types, determining, using a second machine learning system, a particular tool from a plurality of tools associated with the respective tool type to perform a corresponding function from the plurality of functions based on the one or more optimization factors. The example method may further include providing a notification to the user device for display, where the notification may include the architecture pattern, the particular tool for each tool type, and at least one driving optimization factor from the one or more optimization factors.

In other aspects, methods for determining an architecture pattern and tools for an application may be described. An example method may include maintaining a plurality of lists corresponding to a plurality of tool types, each of the plurality of lists including a plurality of tools associated with the respective tool type and pointing to a plurality of characteristics associated with each of the plurality of tools, receiving, from a user device, conversation data between a user and a virtual assistant associated with a use case for an application, and identifying a plurality of functions to serve the use case and one or more keywords associated with each of the plurality of functions based on the conversation data. The example method may also include determining, using a first machine learning system, an architecture pattern for the application based on the plurality of functions, where the architecture pattern may indicate at least a subset of the plurality of tool types for performing the plurality of functions, referencing at least a subset of the plurality of lists corresponding to the subset of the plurality of tool types to identify a subset of the plurality of tools for each tool type having one or more characteristics matching the one or more keywords, and determining, using a second machine learning system, a particular tool from the subset of the plurality of tools for each tool type to perform a corresponding function from the plurality of functions based on the conversation data. The example method may further include providing a notification to the user device for display, where the notification may include the architecture pattern and the particular tool for each tool type and the subset of the plurality of tools for each tool type.

In further aspects, methods for determining an architecture pattern and tools for an application may be described. An example method may include receiving, from a user device, conversation data between a user and a virtual assistant associated with a use case for an application, and identifying a plurality of functions to serve the use case based on the conversation data. The example method may also include determining an architecture pattern for the application based on the plurality of functions, where the architecture pattern may indicate a plurality of tool types for performing the plurality of functions, and for each tool type of the plurality of tool types, determining a particular tool from a plurality of tools associated with the respective tool type to perform a corresponding function from the plurality of functions based on the conversation data. The example method may further include providing the architecture pattern and the particular tool determined for each tool type to the user device for display.

### BRIEF DESCRIPTION OF THE DRAWINGS

The accompanying drawings, which are incorporated in and constitute a part of this specification, illustrate various exemplary aspects and together with the description, serve to explain the principles of the disclosed aspects.

FIG. 1 depicts an exemplary environment for determining architecture patterns and tools for applications, according to certain aspects.

FIG. 2 depicts a flowchart of an exemplary process for determining an architecture pattern and tools for an application, according to certain aspects.

FIG. 3 depicts a flowchart of an exemplary process for determining tools for an application, according to certain aspects.

FIG. 4 depicts a flowchart of an exemplary process for adjusting a determination of tools for an application, according to certain aspects.

FIG. 5A depicts a block diagram of an exemplary process for training and using one or more machine learning models to determine architecture patterns for applications, according to certain aspects.

FIG. 5B depicts a block diagram of an exemplary process 550 for training and using one or more machine learning models to determine tools for applications, according to certain aspects.

FIG. 6 depicts an exemplary notification, according to certain aspects.

FIG. 7 depicts an example of a computer, according to certain aspects.

### DETAILED DESCRIPTION

According to certain aspects of the disclosure, methods and systems are disclosed for determining architecture patterns and tools for applications. As will be discussed in more detail below, in various embodiments, systems and methods are described for determining use case-specific architecture patterns and tools for applications.

As briefly discussed above, conventionally, a solutions and/or systems architect may obtain a use case for an application, identify keywords from the use case, and manually select an architecture pattern and tools for implementing the application based on the keywords using their expert knowledge and experience. However, for any given architecture pattern, there are a large number of tools available from various different service providers for implementation, and new and/or updated tools become available on a frequent basis. Despite the wealth of available tools, it is common for a solutions and/or systems architect to select from a small number of tools that they are most familiar with. Additionally, despite the increase in agnostic tools, the tools selected are often all hosted or provided by a same service provider (e.g., a service provider of the architecture corresponding to the architecture pattern). Resultantly, the set of tools conventionally selected to perform functions for serving the use case may not be the most optimal permutation or combination of tools possible with respect to optimization factors such as cost and/performance.

To address these challenges, systems and methods are described herein for machine-learning based determinations of use case-specific architecture patterns and tools for applications. As described in detail throughout the disclosure, one or more machine learning models may be trained and used to determine an architecture pattern and tools for an application based on a use case for the application.

In an exemplary use case, the application use case, including any desired optimization factors, may be obtained from and/or represented by conversation data (e.g., question and answer data) between a user and a virtual assistant executing on a device of the user. An architecture pattern for the application may be determined based on the conversation data using a first machine learning model. The architecture pattern may indicate a plurality of tool types for performing a plurality of functions to serve the use case. To determine a particular tool for each tool type indicated by the determined architecture pattern, metrics associated with one or more optimization factors included in the conversation data (e.g., optimization factor metrics) for various permutations or combinations of tools of the respective tool types may be determined using a second machine learning model. The optimization factor metrics determined among the permutations or combinations may then be compared or otherwise analyzed in view of the conversation data, and particularly at least one driving optimization factor, to determine a particular tool for each tool type (e.g., based on the permutation or combination of tools determined to be most optimal for the use case).

The permutations or combinations may be determined from lists of tools for respective tool types that are periodically updated to include newly available tools and/or modify characteristics of existing tools included within the lists. Additionally, the permutation or combination of tools determined to be most optimal for the use case may include agnostic tools hosted and/or provided by different service providers than a service provider of the architecture corresponding to the architecture pattern. Further, the determined architecture pattern and tools may be provided to the user in an interactive manner that allows the user to select an alternative driving optimization factor and receive an adjusted determination.

While specific examples included throughout the present disclosure involve architecture patterns and tools for applications, it should be understood that techniques according to this disclosure may be adapted to similar structural components and/or functional tools for other computing resources. It should also be understood that the examples above are illustrative only. The techniques and technologies of this disclosure may be adapted to any suitable activity.

Accordingly, reference to any particular activity is provided in this disclosure only for convenience and is not intended to limit the disclosure. A person of ordinary skill in the art would recognize that the concepts underlying the disclosed devices and methods may be utilized in any suitable activity. The disclosure may be understood with reference to the following description and the appended drawings, wherein like elements are referred to with the same reference numerals.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. Both the foregoing general description and the following detailed description are exemplary and explanatory only and are not restrictive of the features, as claimed.

In this disclosure, the term “based on” may convey “based at least in part on.” The singular forms “a,” “an,” and “the” may include plural referents unless the context dictates otherwise. The term “exemplary” may be used in the sense of “example” rather than “ideal.” The terms “comprises,” “comprising,” “includes,” “including,” or other variations thereof, may convey a non-exclusive inclusion such that a process, method, or product that comprises a list of elements does not necessarily include only those elements, but may include other elements not expressly listed or inherent to such a process, method, article, or apparatus. The term “or” may be interpreted disjunctively, such that “at least one of A or B” includes, (A), (B), (A and A), (A and B), etc. Similarly, the term “or” is intended to mean “and/or,” unless explicitly stated otherwise. “And/or” may convey all permutations, combinations, subcombinations, and individual instances of items or terms included within a list of the items or terms.

Terms like “provider,” “services provider,” or the like may generally encompass an entity or person involved in providing, selling, and/or renting items to persons, as well as an agent or intermediary of such an entity or person. An “item” may generally encompass a good, service, or the like having ownership or other rights that may be transferred, such as architecture assistant services, application architectures and/or functional tools for applications. As used herein, terms like “developer” or “user” generally encompass any person or entity that may develop new and/or modify existing applications. The term “application” may be used interchangeably with other terms like “program,” or the like, and generally encompasses software that is configured to interact with, modify, override, supplement, or operate in conjunction with other software. The term “architecture pattern” may include a type of architecture and/or a provider of the type of architecture for supporting or implementing an application. The term “tools” may include resources configured to perform functions associated with a given architecture pattern to serve a use case for an application.

The term “machine learning model” may generally encompass instructions, data, and/or a model configured to receive input, and apply one or more of a weight, bias, classification, or analysis on the input to generate an output. The output may include, e.g., a classification of the input, an analysis based on the input, a design, process, prediction, or recommendation associated with the input, or any other suitable type of output. A machine learning model is generally trained using training data, e.g., experiential data and/or samples of input data, which are fed into the model in order to establish, tune, or modify one or more aspects of the model, e.g., the weights, biases, criteria for forming classifications or clusters, or the like. The training data may be generated, received, and/or otherwise obtained from internal or external resources. Aspects of a machine learning system may operate on an input linearly, in parallel, via a network (e.g., a neural network), or via any suitable configuration.

The execution of the machine learning model may include deployment of one or more machine learning techniques, such as linear regression, logistical regression, random forest, gradient boosted machine (GBM), deep learning, and/or a deep neural network. Supervised and/or unsupervised training may be employed. For example, supervised learning may include providing training data and labels corresponding to the training data, e.g., as ground truth. Unsupervised approaches may include clustering, classification, or the like. K-means clustering or K-Nearest Neighbors may also be used, which may be supervised or unsupervised. Combinations of K-Nearest Neighbors and an unsupervised cluster technique may also be used. Any suitable type of training may be used, e.g., stochastic, gradient boosted, random seeded, recursive, epoch or batch-based, etc. Alternatively, reinforcement learning may be employed for training. For example, reinforcement learning may include training an agent interacting with an environment to make a decision based on the current state of the environment, receive feedback (e.g., a positive or negative reward based on accuracy of decision), adjusts its decision to maximize the reward, and repeat again until a loss function is optimized.

Presented below are various aspects of machine learning techniques that may be adapted for determining architecture patterns and/or tools for applications. As will be discussed in more detail below, the machine learning techniques may include one or more aspects according to this disclosure, e.g., a particular selection of training data, a particular training process for the machine learning models, operation of the machine learning models in conjunction with particular data, modification of such particular data by the machine learning models, etc., and/or other aspects that may be apparent to one of ordinary skill in the art based on this disclosure.

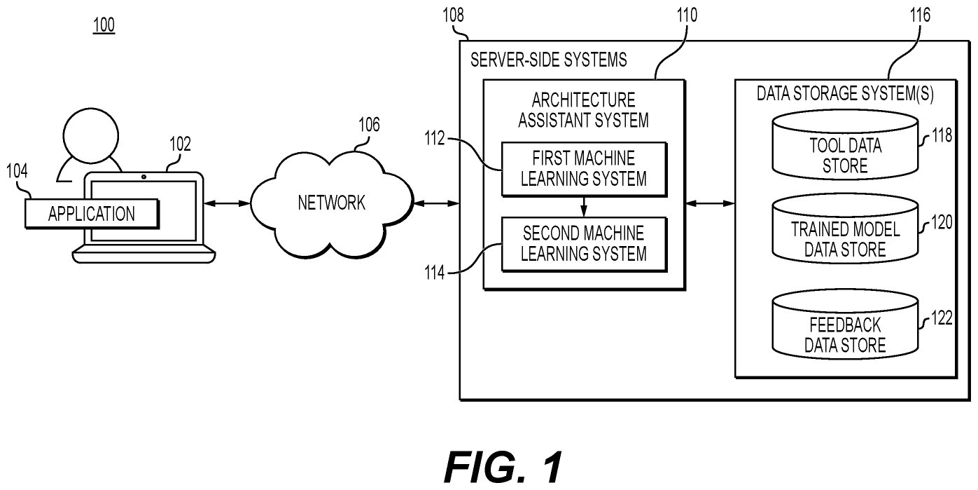

FIG. 1 depicts an exemplary environment 100 for determining architecture patterns and tools for applications, according to certain aspects, and which may be used with the techniques presented herein. A user device 102 of a user may communicate with one or more of the other components of the environment 100 across electronic network 106, including one or more server-side systems 108, discussed below, to initiate a determination of an architecture pattern and tools for an application being developed and/or modified by the user, for example. The environment 100 of FIG. 1 shows one user device 102. However, in other examples, there may be a plurality of user devices 102 that are each communicating with one or more server-side systems 108 to initiate similar determinations for a plurality of applications.

The server-side systems 108 may include an architecture assistant system 110 and/or a plurality of data storage systems 116, among other systems. In some examples, the architecture assistant system 110 and/or one or more of the data storage systems 116, may be associated with a common entity, e.g., a provider of architecture assistant services. In such an example, the server-side systems 108 associated with the common entity may be part of a cloud service computer system (e.g., in a data center). In other examples, one or more of the components of the environment 100 may be associated with a different entity than another. For example, the architecture assistant system 110 may be associated with the provider, and one or more of the data storage systems 116 may be associated with one or more third parties that provide data storage services to the provider.

The above-provided examples are exemplary and non-limiting. The systems and devices of the environment 100 may communicate in any arrangement. As will be discussed herein, systems and/or devices of the environment 100 may communicate in order to enable determination of architecture patterns and tools for applications, among other activities.

The user device 102 may be configured to enable the user to access and/or interact with other systems in the environment 100. For example, the user device 102 may be a computer system such as, for example, a desktop computer, a laptop computer, a tablet, a smart cellular phone, a smart watch or other electronic wearable, etc. In some embodiments, the user device 102 may include one or more electronic applications, e.g., a program, plugin, browser extension, etc., installed on a memory of the user device 102. In some embodiments, the electronic applications may be associated with one or more of the other components in the environment 100. For example, an application 104 associated with the architecture assistant system 110 may be executed on the user device 102 to enable initiation of the architecture assistant services to determine an architecture pattern and tools for an application being developed and/or modified by the user of the user device 102. In some examples, the applications may be thick client applications installed locally on the user device 102 and/or thin client applications (e.g., web applications) that are rendered via the web browser launched on the user device 102.

Additionally, one or more components of the user device 102 may generate, or may cause to be generated, one or more graphic user interfaces (GUIs) based on instructions/information stored in the memory, instructions/information received from the other systems in the environment 100, and/or the like and may cause the GUIs to be displayed via a display of the user device 102. The GUls may be, e.g., application interfaces or browser user interfaces and may include text, input text boxes, selection controls, and/or the like. The display may include a touch screen or a display with other input systems (e.g., a mouse, keyboard, etc.) for the user to control the functions of user device 102.

The architecture assistant system 110 may include one or more server devices (or other similar computing devices) for executing architecture assistant services. Example architecture assistant services may broadly include tasks associated with: facilitating a conversation between the user and a virtual assistant (e.g., of the application 104 associated with the architecture assistant system 110) executing on the user device 102 to obtain conversation data associated with a use case for an application being developed and/or modified by the user; determining a use case-specific architecture pattern and tools for the application; generating one or more notifications to display the determined architecture pattern and tools to the user on the user device 102; and/or adjusting the determined architecture pattern and/or tools based on input received from user interactions with the notifications via the user device 102. Additional services may be offered in conjunction with the architecture assistant services, such as application deployment and/or management services. For example, the application may be automatically deployed in accordance with the determined architecture pattern and/or tools and subsequently managed.

In some examples, the architecture assistant system 110 may include a first machine learning system 112 and a second machine learning system 114. The first machine learning system 112 may be configured to determine the architecture pattern for the application based on a plurality of functions identified as serving a particular use case for the application. The particular use case may be extracted from the conversation data obtained between the user of the user device 102 and the virtual assistant. The second machine learning system 114 may be configured to determine tools for the application based on the architecture pattern determined by the first machine learning system 112. For example, the determined architecture pattern may indicate a plurality of tool types for performing the plurality of functions to serve the particular use case. For each tool type, the second machine learning system 114 may be configured to determine a particular tool associated with the respective tool type to perform a corresponding function from the plurality of functions. In some examples, the determination may be based on optimization factors included in the conversation data.

The data storage systems 116 may include a server system or computer-readable memory such as a hard drive, flash drive, disk, etc. In some examples, the data storage systems 116 may include and/or interact with an application programming interface for exchanging data to other systems, e.g., one or more of the other components of the environment 100, such as the architecture assistant system 110. In other examples, one or more of the data storage systems 116 may be a sub-system or component of the architecture assistant system 110 (e.g., when the one or more data storage systems 116 are also provided by the provider rather than a third party).

The data storage systems 116 may include and/or act as a repository or source for various types of data for the architecture assistant services. For example, the data storage systems 116 may include a plurality of data stores, including a tool data store 118, a trained model data store 120, and/or a feedback data store 122. The tool data store 118 may be configured to store a plurality of lists that are referenced by the architecture assistant system 110 to determine tools for the application. The trained model data store 120 may be configured to store one or more trained models that are retrieved and executed by the first machine learning system 112 and/or the second machine learning system 114 of the architecture assistant system 110 to determine architecture patterns and/or tools for applications, respectively. The feedback data store 122 may be configured to store feedback or monitoring data that is collected when the architecture pattern and tools determined by the architecture assistant system 110 are implemented and the application is deployed, for example. The feedback may be used to update or adjust the one or more trained models to improve the accuracy thereof, as described in detail elsewhere herein.

The network 106 over which the one or more components of the environment 100 communicate may include one or more wired and/or wireless networks, such as a wide area network (“WAN”), a local area network (“LAN”), personal area network (“PAN”), a cellular network (e.g., a 3G network, a 4G network, a 5G network, etc.) or the like. In some embodiments, the network 106 includes the Internet, and information and data provided between various systems occurs online. “Online” may mean connecting to or accessing source data or information from a location remote from other devices or networks coupled to the Internet. Alternatively, “online” may refer to connecting or accessing an electronic network (wired or wireless) via a mobile communications network or device. The user device 102 and one or more of the server-side systems 108 may be connected via the network 106, using one or more standard communication protocols. The user device 102 and one or more of the server-side systems 108 may transmit and receive communications from each other across the network 106, as discussed in more detail below.

Although depicted as separate components in FIG. 1, it should be understood that a component or portion of a component in the system of exemplary environment 100 may, in some embodiments, be integrated with or incorporated into one or more other components. For example, the second machine learning system 114 may be integrated with the first machine learning system 112, one or more of the data storage systems 116 may be integrated with the architecture assistant system 110, or the like. In some embodiments, operations or aspects of one or more of the components discussed above may be distributed amongst one or more other components. Any suitable arrangement and/or integration of the various systems and devices of the exemplary environment 100 may be used.

In the following disclosure, various acts may be described as performed or executed by a component from FIG. 1, such as the user device 102 or one or more of the server-side systems 108, or components thereof. However, it should be understood that in various embodiments, various components of the exemplary environment 100 discussed above may execute instructions or perform acts including the acts discussed below. An act performed by a device may be considered to be performed by a processor, actuator, or the like associated with that device. Further, it should be understood that in various embodiments, various steps may be added, omitted, and/or rearranged in any suitable manner.

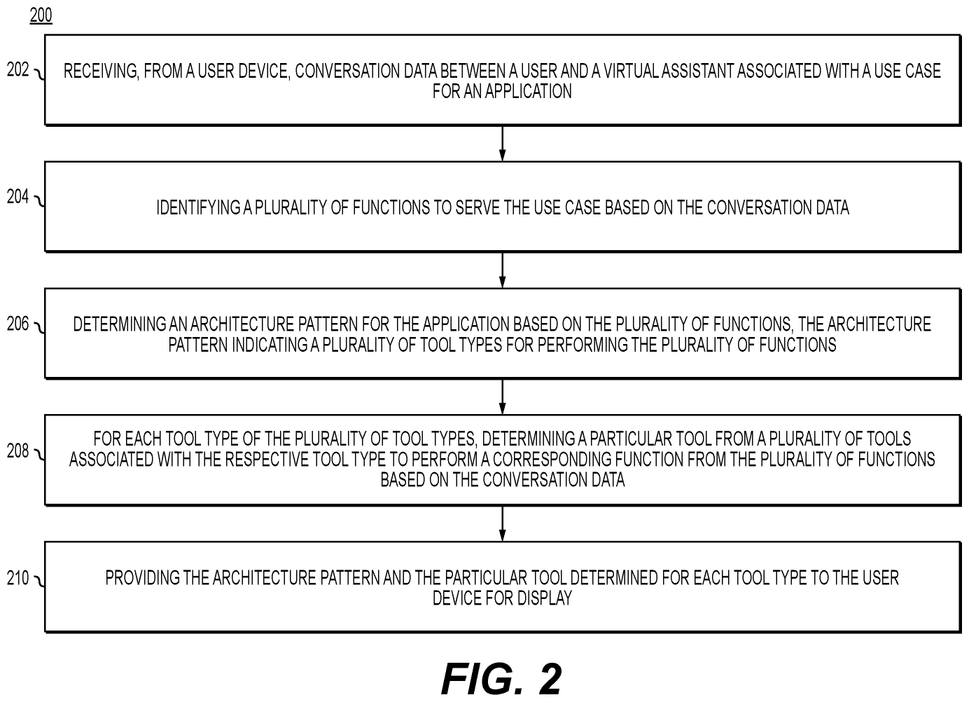

FIG. 2 depicts a flowchart of an exemplary process 200 for determining an architecture pattern and tools for an application. In some examples, various steps of the process 200 may be performed by the architecture assistant system 110.

At step 202, the process 200 may include receiving, from the user device 102, conversation data between a user and a virtual assistant associated with a use case for an application. The conversation data may include business requirements, context, and/or one or more optimization factors associated with the application. Example optimization factors may be associated with cost, performance, and/or reliability. In some examples, the performance and/or reliability-related optimization factors may be defined by associated metrics, including response time, throughput, CPU utilization, error-rate, recovery point objective (RPO), recovery time objective (RTO), and/or latency, among other similar examples.

In some examples, the virtual assistant may be a feature of the application 104 associated with the architecture assistant system 110 that is executing on the user device 102. The virtual assistant may be a rule-based chatbot. Alternatively, the virtual assistant may be an artificial intelligence-based chatbot. The virtual assistant may facilitate and record a conversation with the user to generate conversation data.

In some examples, the conversation data may include question and answer data. The questions may be formulated to obtain, via corresponding answers, an understanding of the specific use case for the application. Example questions may include “What kind of architecture do you prefer (e.g., cloud vs. in-house servers)?”, “Which service provider do you prefer?”, or the like. Additionally, the answer to a question may determine a next question to be presented by the virtual assistant. An example conversation flow may be as follows: Will this application need a remote database? If so, is the application performing lots of write operations, or mainly reads? Does the application need to preserve user session data? If so, is the amount of preserved user session data greater than a threshold amount such that a cache should be implemented, or would cookies be a reasonable approach? Should this application present differently based on what country or region a client is in, etc.

In some examples, the potential answers to a question may be predefined and provided as options to the user for selection (e.g., the answers may be received as structured data). In other examples, a text box may be provided to enable the user to provide a freeform answer to one or more of the questions (e.g., the answers may be received as unstructured data). In such examples, one or more natural language processing techniques may be run to further process the conversation data and/or to convert the data to a structured format.

At step 204, the process 200 may include identifying a plurality of functions to serve the use case based on the conversation data. Example functions may include storage functions, load balancing (e.g., routing) functions, compute functions, and/or other similar functions that may be necessary to provide or support the use case (e.g., to support the business requirements, context, etc.).

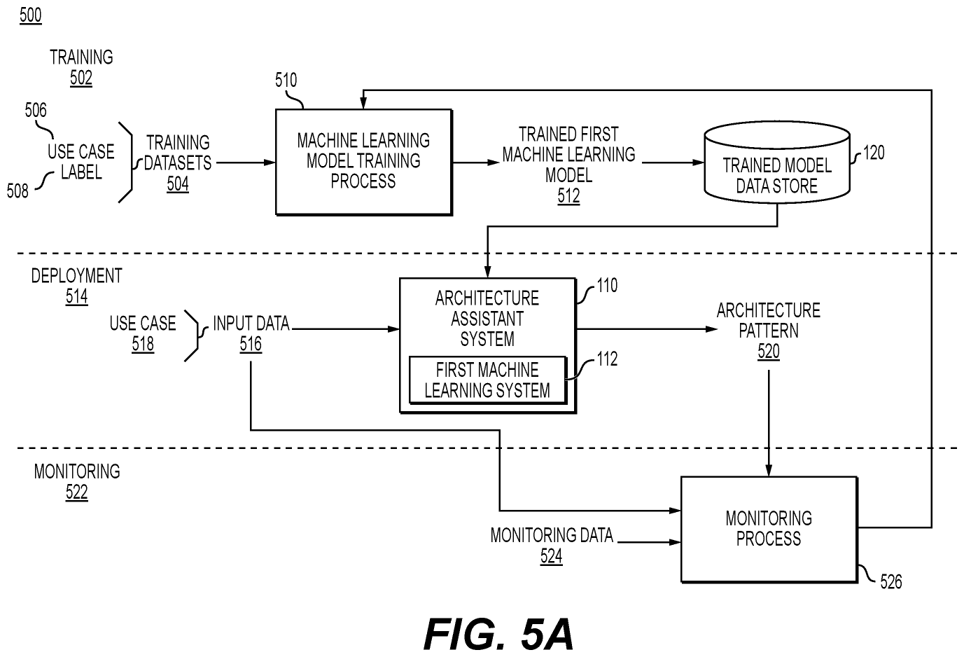

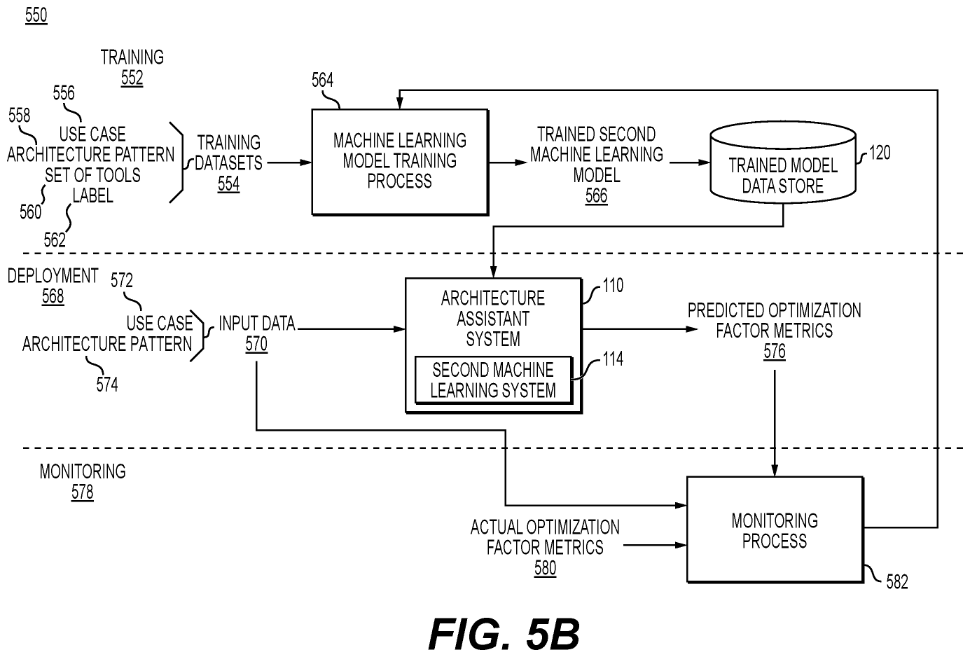

At step 206, the process 200 may include determining an architecture pattern for the application based on the plurality of functions. The architecture pattern may indicate a plurality of tool types for performing the plurality of functions. For example, the architecture pattern may indicate one or more storage tool types for performing storage functions, one or more load balancing tool types for performing load balance functions, one or more computing tool types for performing compute functions, etc. The architecture pattern determined may be a pattern that is optimal for performing the plurality of functions for the use case informed by the conversation data. The architecture pattern may be determined using the first machine learning system 112. In some examples, the first machine learning system 112 may retrieve (e.g., from the trained model data store 120) and execute a first machine learning model to determine the architecture pattern based on the conversation data. In some examples, the first machine learning model may be a classification model configured to classify textual description from the conversation data into defined categories corresponding to a plurality of architecture patterns. Additionally, the first machine learning model may utilize a bucketization and/or binning algorithm, among other feature engineering techniques, to facilitate the classification. Example processes for training and using the first machine learning system 112 are described below with reference to FIG. 5A.

At step 208, the process 200 may include, for each tool type of the plurality of tool types, determining a particular tool from a plurality of tools associated with the respective tool type to perform a corresponding function from the plurality of functions based on the conversation data. Specifically, in some examples, the determination may be based on at least one of the one or more optimization factors (e.g., at least one driving optimization factor) included in the conversation data.

In some examples, the particular tool for each tool type may be determined using the second machine learning system 114. For example, the second machine learning system 114 may retrieve (e.g., from the trained model data store 120) and execute a second machine learning model trained to predict metrics associated with one or more of the optimization factors included in the conversation data (e.g., optimization factor metrics) for various permutations or combinations of particular tools of the respective tool types. The permutations or combinations may be derived, for example, from the lists associated with the tool types (stored in the tool data store 118) that are indicated by the architecture pattern determined at step 206. In some examples, the second machine learning model may be trained for or specific to the architecture pattern determined at step 206 (e.g., based on the functions provided by the architecture pattern). In other examples, the second machine learning model may be trained generally such that it is a common model applied to various types of architecture patterns. In such examples, the functions of the architecture pattern may be provided, among other data, as input to the second machine learning model. Example processes for training, using, and monitoring the second machine learning model of the second machine learning system 114 are described below with reference to FIG. 5B.

The optimization factor metrics predicted by the second machine learning model for each permutation or combination of tools may then be compared in view of the optimization factors included in the conversation data, and particularly the at least one driving optimization factor, to determine a particular tool for each tool type indicated by the architecture pattern. In other words, groupings of various tools that perform the same functions (e.g., storage tools, load balancing tools, compute tools, etc.) but in different ways may be compared using the optimization factor metrics to select an optimal set of tools for performing the functions to serve a given use case with indicated optimization factors (e.g., cost, performance, etc.). For example, the permutation or combination of the particular tools of the respective tool types having the most beneficial predicted optimization factor metrics for the at least one driving optimization factor for the use case (e.g., lowest cost, highest performance, etc.) may be the tools determined.

To provide an illustrative example, the conversation data may indicate cost as the driving optimization factor, and the second machine learning model may predict a cost of a first permutation or combination of five tools to perform the plurality of functions to serve the use case as X dollars, and a cost of a second permutation or combination of four tools (e.g., a different approach) to perform the same plurality of functions to serve the use case as Y dollars, where Y is greater than X. In such an example, the first permutation or combination of five tools may be selected or determined at step 208 given the lower cost to perform the same functions to serve the use case.

In some examples, the particular tool determined for each tool type may be associated with a same service provider (e.g., all the determined tools are hosted or provided by a same entity). In other examples, the particular tool for at least one of the plurality of tool types is associated with a different service provider than the particular tool for one or more other of the plurality of tool types. For example, a determined storage-related tool may be hosted by a first service provider, while a load balancing and/or computing power-related tool may be hosted by a second service provider different from the first service provider.

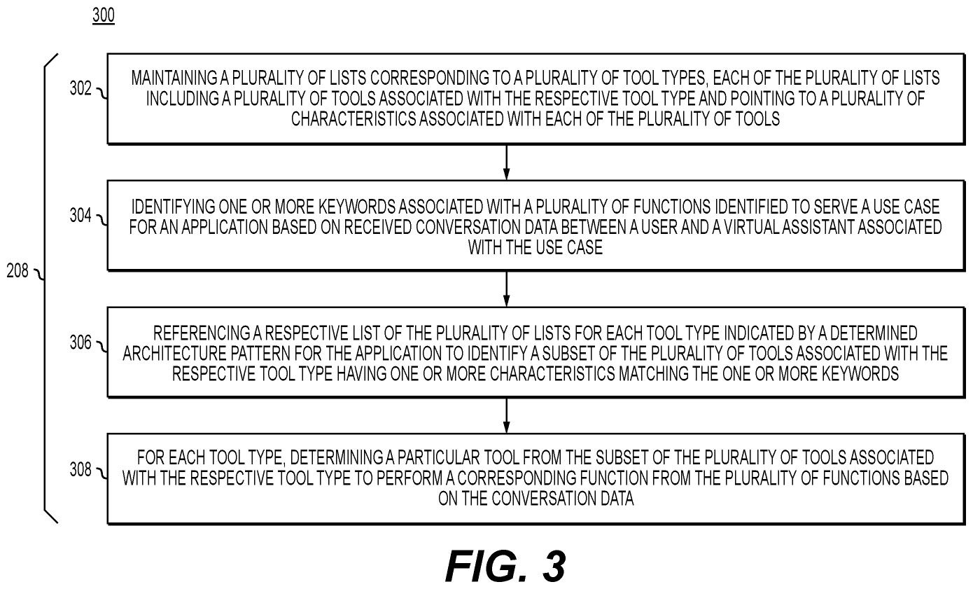

In some examples, and as discussed in more detail with reference to FIG. 3, the particular tool for each tool type may be determined from a subset of the plurality of tools associated with the respective tool type. The subset may be identified based on an analysis of characteristics associated with the tools and keywords (and/or phrases) identified from the conversation data. For example, the tool data store 118 may store a plurality of lists corresponding to the plurality of tool types, where each of the lists may include the plurality of tools associated with the respective tool type and point to a plurality of characteristics associated with each of the plurality of tools. The keywords may be analyzed (e.g., matched) against the characteristics within the lists.

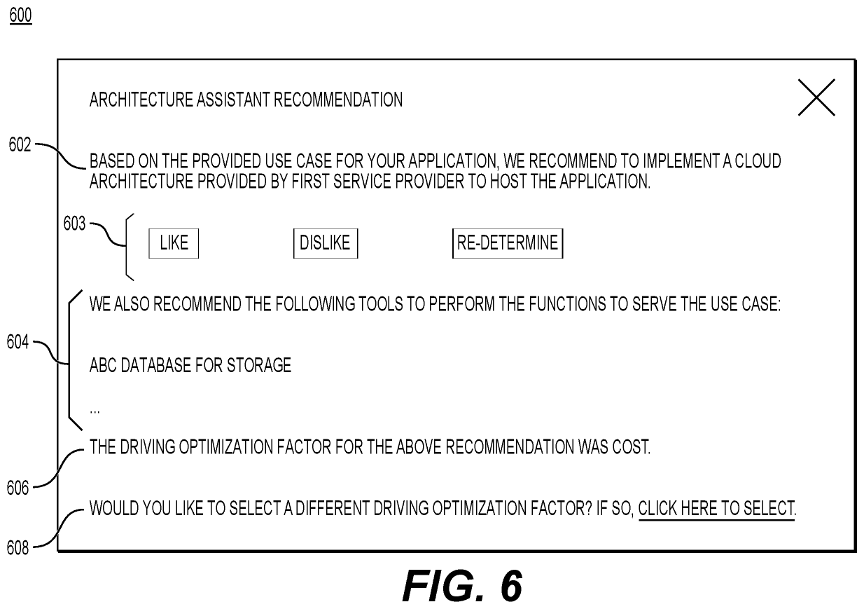

At step 210, the process 200 may include providing the architecture pattern and the particular tool determined for each tool type to the user device 102 for display. In some examples, a notification may be generated and provided to the user device 102 for display. An example notification is described with reference to FIG. 6 below. The notification may include at least the architecture pattern and the particular tool for each tool type. Additionally, matching keywords from the conversation data and/or other information associated with the architecture pattern and/or tools that indicate or highlight a reasoning for the determination may be displayed within the notification. In some aspects, implementation and/or management of the application implemented in accordance with the architecture pattern and/or particular tools may be offered as an additional service (e.g., by a provider of the architecture assistant system 110). Additionally or alternatively, supplemental information and/or links to such information may be provided within the notification to facilitate implementation of the application by the user in accordance with the architecture pattern and/or particular tools.

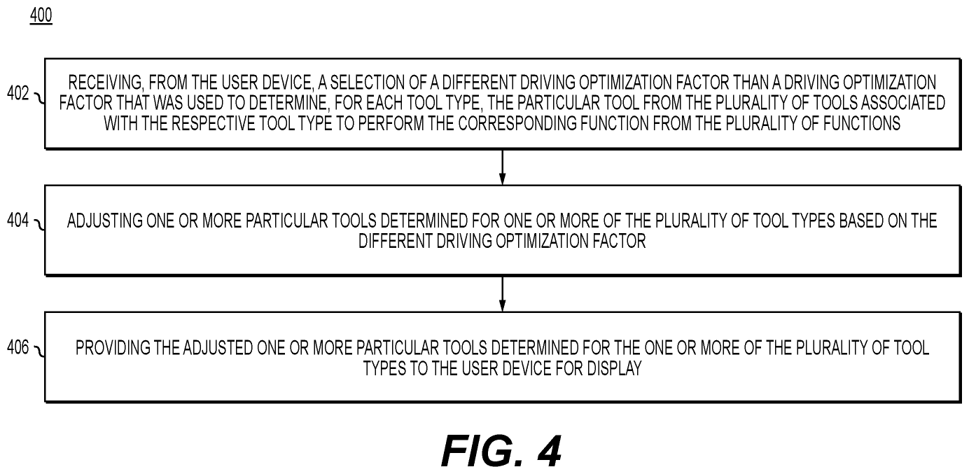

In some examples, the notification may also include the at least one driving optimization factor used to make the determination. Additionally, the notification may further include an option to select a different driving optimization factor. As described in more detail with reference to FIG. 4 below, when a selection of the different driving optimization factor is received from the user device 102, one or more of the particular tools determined for one or more of the tool types may be adjusted based on the different driving optimization factor. An updated notification may then be provided to the user device 102 for display based on the adjustment.

Also, feedback data may be solicited from the user of the user device 102 via the notification. For example, the notification may include selectable control elements indicating the user's response or feedback (e.g., like, dislike, re-determine, etc.) to the determined architecture pattern and/or particular tools. A control element selected may be received and stored in the feedback data store 122 for use in updating or retraining the machine learning models executed by the first machine learning system 112 and/or the second machine learning system 114 to improve an accuracy and/or robustness thereof. As one example, and as described in more detail with reference to FIG. 5A below, feedback data associated with at least the determined architecture pattern may be collected, and the first machine learning model executed by the first machine learning system 112 may be retrained accordingly

Further, once the architecture pattern and the particular tool for each tool type are implemented and the application is deployed, metrics-based feedback data may be collected and stored in the feedback data store 122. The metrics-based feedback data may similarly be used for updating or retraining the machine learning models executed by the first machine learning system 112 and/or the second machine learning system 114. As one example, and as described in more detail with reference to FIG. 5B below, feedback data associated with the at least one driving optimization factor (e.g., optimization factor metrics) may be collected, and the second machine learning model executed by the second machine learning system 114 may be retrained accordingly. In some examples, the feedback data associated with the at least one driving optimization factor may be collected per function. For example, if the driving optimization factor is cost, an actual cost of implementing the application may be the metric type collected or monitored automatically and/or may be requested from the user. In some examples, the actual cost may be divisible or separable per function. For example, an actual cost for storage, an actual cost for load balancing, and an actual cost for compute may be separately collected and utilized for retraining.

Accordingly, certain aspects may include determining an architecture pattern and tools for an application. The process 200 described above is provided merely as an example, and may include additional, fewer, different, or differently arranged steps than depicted in FIG. 2.

FIG. 3 depicts a flowchart of an exemplary process 300 for determining tools for an application. In some examples, various steps of the process 300 may be performed by the architecture assistant system 110. One or more of steps 302-308 of the process 300 may be used to perform at least part of step 208 of the process 200 described with reference to FIG. 2.

At step 302, the process 300 may include maintaining a plurality of lists corresponding to a plurality of tool types. Each of the lists may include a plurality of tools associated with the respective tool type and point to a plurality of characteristics associated with each of the tools. For example, a first list may include a first plurality of tools associated with storage mechanisms, a second list may include a second plurality of tools associated with load balancing, a third list may include a third plurality of tools associated with compute power, and so on. Example characteristics may include advantages and/or disadvantages (e.g., pro and/or cons) of the particular tool.

In some examples, the lists may be stored in the tool data store 118, and maintained by periodically scraping website data from websites associated with and/or providing information on the tools. The website data may be scraped to identify new tools and associated characteristics and/or modifications to characteristics associated with existing tools for use in updating the lists. In some examples, one or more of the lists may be stored in a form of a hash map or a dictionary, and each tool included in the list is a key mapped to values representing the characteristics associated with the respective tool.

At step 304, the process 300 may include identifying one or more keywords associated with a plurality of functions identified to serve a use case for an application. The functions may be identified based on received conversation data between a user and a virtual assistant associated with the use case, as described in detail with reference to steps 202 and 204 of the process 200 of FIG. 2. The keywords may be identified and extracted from the conversation data. Exemplary, non-limiting keywords may include throughput-oriented or latency oriented.

At step 306, the process 300 may include referencing a respective list of the plurality of lists for each tool type indicated by a determined architecture pattern for the application to identify a subset of the plurality of tools associated with the respective tool type having one or more characteristics matching the one or more keywords. The architecture pattern may be determined based on the plurality of functions identified to serve the use case for an application, as described in detail with reference to step 206 of the process 200 of FIG. 2. In some examples, the architecture pattern may further be determined based on one or more of the keywords associated with the plurality of functions that are identified and extracted from the conversation data.

To provide an illustrative example, one of the keywords extracted from the conversation data may be “throughput-oriented” associated with a storage function. In this example, a list that includes a plurality of storage tools may be referenced to identify a subset of the storage tools within the list that have high throughput characteristics (e.g., tools having amount of data transferred to and from the storage device per second be above a threshold value).

At step 308, the process 300 may include, for each tool type, determining a particular tool from the subset of the plurality of tools associated with the respective tool type to perform a corresponding function from the plurality of functions based on the conversation data. The particular tool may be determined using the second machine learning system 114 as described in detail with reference to step 208 of the process 200 of FIG. 2.

Accordingly, certain aspects may include determining tools for an application. The process 300 described above is provided merely as an example, and may include additional, fewer, different, or differently arranged steps than depicted in FIG. 3.

FIG. 4 depicts a flowchart of an exemplary process 400 for adjusting a determination of tools for an application. In some examples, various steps of the process 400 may be performed by the architecture assistant system 110. The process 400 may follow step 210 of the process 200 described with reference to FIG. 2. At step 402, the process 400 may include receiving, from the user device 102, a selection of a different driving optimization factor than a driving optimization factor that was used to determine, for each tool type, the particular tool from the plurality of tools (or subset thereof) associated with the respective tool type to perform the corresponding function from the plurality of functions.

For example, the architecture pattern and the particular tool determined for each tool type may be provided to the user device 102 for display within a notification. In addition to the architecture pattern and the tools, the notification may also include the driving optimization factor from the one or more optimization factors included in the conversation data that was used at least as part of the determination of the tools at step 208 of the process 200 (e.g., a first driving optimization factor). The notification may further include an option to select the different driving optimization factor (e.g., a second driving optimization factor). The selection may be received at step 402 in response to a user selection of the option within the notification. As one exemplary, non-limiting example, the first driving optimization factor may be cost, whereas the second driving optimization factor may be performance.

At step 404, the process 400 may include adjusting one or more particular tools determined for one or more of the plurality of tool types based on the different driving optimization factor. For example, one or more of the tools initially determined based on cost optimization may be replaced by tools that are better configured for performance. To perform the adjustment, the tool determination at step 208 of the process 200 may be repeated, where the different driving optimization factor is provided as part of the input to the second machine learning model retrieved and executed by the second machine learning system 114 to perform the tool determination.

At step 406, the process 400 may include providing the adjusted one or more particular tools determined for the one or more of the plurality of tool types to the user device 102 for display. For example, an updated notification including the adjusted tool(s) may be provided to the user device 102 for display.

In some examples, the process 400 may be repeated one or more times to allow the user to choose among various different optimization factors to determine how the factors affect at least the determined tools. Additionally, in some aspects, based on the different optimization factors selected, the architecture pattern may also be adjusted. For example, the architecture pattern determination may also be repeated, where the different driving optimization factor is provided as part of the input to the first machine learning model retrieved and executed by the first machine learning system 112 to perform the architecture pattern determination.

Accordingly, certain aspects may include adjusting a determination of tools for an application. The process 400 described above is provided merely as an example, and may include additional, fewer, different, or differently arranged steps than depicted in FIG. 4.

FIG. 5A depicts a block diagram of an exemplary process 500 for training and using one or more machine learning models to determine architecture patterns for applications. In some examples, the first machine learning system 112 of the architecture assistant system 110 may perform generating, storing, training, and/or using a first machine learning model configured to determine architecture patterns for applications. The first machine learning system 112 may include the first machine learning model and/or instructions associated with the first machine learning model, e.g., instructions for generating a first machine learning model, training the first machine learning model, using the first machine learning model, etc. In other embodiments, a system or device other than the first machine learning system 112 may be used to generate and/or train the first machine learning model. For example, such a system may include instructions for generating the first machine learning model and the training data, and/or instructions for training the first machine learning model. A resulting trained first machine learning model may then be provided to the first machine learning system 112 for use.

As depicted in FIG. 5A, in some examples, the process 500 may include a training phase 502, a deployment phase 514, and a monitoring phase 522. In the training phase 502, at step 510, the process 500 may include receiving and processing a plurality of training datasets 504 to generate (e.g., build) a trained first machine learning model 512 for determining an architecture pattern for an application based on a specific use case for the application.

An exemplary training dataset of the plurality of training datasets 504 may include a use case 506 for an application. In some examples, the use case 506 may be a textual description (e.g., derived from conversation data or otherwise) and include at least associated keywords and/or phrases. The exemplary training set may also include a corresponding label 508 that indicates an architecture pattern for the application that serves the use case 506. The training datasets 504 may be generated, received, or otherwise obtained from internal and/or external resources. Exemplary external resources may include databases storing practice or test questions that describe an application use case and associated answers indicating the architecture pattern to serve the use case that are used as part of a certification process for certifying individuals as solution or systems architects or other similar specialists.

Generally, a model includes a set of variables, e.g., nodes, neurons, filters, etc., that are tuned, e.g., weighted or biased, to different values via the application of the training datasets 504. The model may be a text classification model configured to classify the textual description of the use case 506 into defined categories or classes corresponding to a plurality of architecture patterns.

Additionally, the model may utilize bucketization or binning (e.g., implement a bucketization or binning algorithm), among other feature engineering techniques, to facilitate a categorization of a plurality of continuous variables extracted from the training datasets 504 into discrete groups. For example, an architecture intent may be derived from the text description of the use case 506 for use in inferring or predicting a corresponding architecture pattern. To derive the architecture intent, categorical binning may be implemented by tracking a number of keywords and/or phrases in the text description (e.g., a number of tokens) that are associated with, correspond to, or otherwise relate to each of the plurality of architectures (e.g., each represented by a bin). The association or relation of a keyword to a given architecture may be determined based on a maintained list of keywords that are associated with the given architecture. To provide an illustrative example, if there are ten different architectures, a list of keywords and/or phrases associated with each of the ten architectures may be maintained. Accordingly, the model may include 10 variables (e.g., 1 variable for each of the different architectures or bins), and a value associated with each of the variables that is input to the model may be based on a number of architecture-specific keywords and/or phrases (e.g., tokens) tracked.

In some examples, the training process at step 510 may employ supervised, unsupervised, semi-supervised, and/or reinforcement learning processes to train the model (e.g., to result in trained first machine learning model 512). In some embodiments, a portion of the training datasets 504 may be withheld during training and/or used to validate the trained first machine learning model 512.

When supervised learning processes are employed, the labels corresponding to the training datasets 504 (e.g., label 508) described above may facilitate the learning process by providing a ground truth. Training may proceed by feeding a use case 506 of a training dataset (e.g., a sample) from the training datasets 504 into the model, the model having variables set at initialized values, e.g., at random, based on Gaussian noise, a pre-trained model, or the like. The model may output an architecture pattern for the sample (e.g., predict an architecture pattern configured to support functions that will serve the use case 506). The output may be compared with the corresponding label 508 or score (e.g., the ground truth) indicating the optimal architecture pattern to serve the use case 506 to determine an error, which may then be back-propagated through the model to adjust the values of the variables. This process may be repeated for a plurality of samples at least until a determined loss or error is below a predefined threshold. In some examples, some of the training datasets 504 may be withheld and used to further validate or test the trained first machine learning model 512.

For unsupervised learning processes, the training datasets 504 may not include pre-assigned labels or scores to aid the learning process. Rather, unsupervised learning processes may include clustering, classification, or the like to identify naturally occurring patterns in the training datasets 504. K-means clustering or K-Nearest Neighbors may also be used, which may be supervised or unsupervised. Combinations of K-Nearest Neighbors and an unsupervised cluster technique may also be used. For semi-supervised learning, a combination of training datasets 504 with pre-assigned labels or scores and training datasets 504 without pre-assigned labels or scores may be used to train the model.

When reinforcement learning is employed, an agent (e.g., an algorithm) may be trained to make a decision regarding the architecture pattern for the sample from the training datasets 504 through trial and error. For example, upon making a decision, the agent may then receive feedback (e.g., a positive reward if the predicted architecture pattern is the optimal architecture pattern), adjust its next decision to maximize the reward, and repeat until a loss function is optimized.

Once trained, the trained first machine learning model 512 may be stored (e.g., in the trained model data store 120) and subsequently applied by the first machine learning system 112 during the deployment phase 514. For example, during the deployment phase 514, the trained first machine learning model 512 executed by the first machine learning system 112 may receive input data 516. The input data 516 may include a use case 518 for an application. In some examples, the use case 518 may be derived or otherwise identified or extracted from obtained conversation data between a user and a virtual assistant that is associated with the use case for the application (e.g., may include at least keywords and/or phrases identified from the conversation data).

The trained first machine learning model 512 may provide, as output data, an architecture pattern 520 for the application to serve the use case 518. In some examples, the architecture pattern 520 may be provided as input into other processes (not shown), such as to determine tools of respective tool types for performing the functions supported by the architecture pattern 520 to serve the use case 518, as described in detail with reference to FIG. 5B.

During the monitoring phase 522, feedback associated with the output data of the trained first machine learning model 512 may be received as monitoring data 524 and stored in the feedback data store 122. For example, the monitoring data 524 may include feedback solicited from the user. In some aspects, the feedback may be solicited through a same notification that is used to provide the determined architecture pattern 520 to the user. For example, the notification may include selectable control elements indicating the user's response or feedback to the architecture pattern 520 (e.g., like, dislike, re-determine, etc.). A control element may be received and stored as monitoring data 524. Additionally or alternatively, the monitoring data 524 may include feedback solicited from a solutions or systems architect specialist (e.g., serving as a reviewer or analyst) that indicates a most optimal architecture pattern for the use case 518 that is collected during the monitoring phase 522. During a monitoring process 526, the monitoring data 524 may be analyzed along with the architecture pattern 520 and the input data 516 to determine an accuracy of the trained first machine learning model 512. In some examples, based on the analysis, the process 500 may return to the training phase 502, where at step 510 values of one or more variables of the trained first machine learning model 512 may be adjusted to improve the accuracy of the trained first machine learning model 512. For example, the most optimal architecture pattern for the use case 518 indicated by the monitoring data 524 may be used as a label (e.g., similar to the label 508) to create a new training dataset 504 for use in retraining the trained first machine learning model 512. In some examples, the trained first machine learning model 512 may be retrained after a predefined number of new training datasets 504 have been received.

FIG. 5B depicts a block diagram of an exemplary process 550 for training and using one or more machine learning models to determine tools for applications. Additionally, in some examples, the second machine learning system 114 of the architecture assistant system 110 may one or more of generate, store, train, or use a second machine learning model configured to determine tools for applications, where the determined tools may be based on output of the first machine learning system 112 (e.g., based on an architecture pattern for an application determined by the trained first machine learning model 512). The second machine learning system 114 may include the second machine learning model and/or instructions associated with the second machine learning model, e.g., instructions for generating a second machine learning model, training the second machine learning model, using the second machine learning model, etc. In other embodiments, a system or device other than the second machine learning system 114 may be used to generate and/or train the second machine learning model. For example, such a system may include instructions for generating the second machine learning model and the training data, and/or instructions for training the second machine learning model. A resulting trained second machine learning model may then be provided to the second machine learning system 114 for use.

As depicted in FIG. 5B, in some examples, the process 550 may include a training phase 552, a deployment phase 568, and a monitoring phase 578. In the training phase 552, at step 564, the process 550 may include receiving and processing a plurality of training datasets 554 to generate (e.g., build) a trained second machine learning model 566 for determining tools for an application.

An exemplary training dataset of the plurality of training datasets 554 may include a use case 556 for an application, an architecture pattern 558, and a set of particular tools 560 of tool types indicated by the architecture pattern for performing functions to serve the application use case. The exemplary training set may also include a corresponding label 562 that indicates one or more observed metrics associated with one or more optimization factors. The training datasets 554 may be generated, received, or otherwise obtained from internal and/or external resources.

Generally, a model includes a set of variables, e.g., nodes, neurons, filters, etc., that are tuned, e.g., weighted or biased, to different values via the application of the training datasets 554. In some examples, the training process at step 564 may employ supervised, unsupervised, semi-supervised, and/or reinforcement learning processes to train the model (e.g., to result in trained second machine learning model 566). In some embodiments, a portion of the training datasets 554 may be withheld during training and/or used to validate the trained second machine learning model 566.

When supervised learning processes are employed, the labels corresponding to the training datasets 554 (e.g., label 562) described above may facilitate the learning process by providing a ground truth. Training may proceed by feeding a training dataset 554, including a use case 556, an architecture pattern 558, and a set of particular tools 560 (e.g., a sample) from the training datasets 554 into the model, the model having variables set at initialized values, e.g., at random, based on Gaussian noise, a pre-trained model, or the like. The model may output predicted metrics associated with one or more optimization factors for the sample (e.g., predict metrics associated with cost, performance, etc. of the application when the architecture pattern 558 and the set of particular tools 560 are implemented in the context of the use case 556). The output may be compared with the corresponding label 562 or score (e.g., the ground truth) indicating the actual or observed metrics to determine an error, which may then be back-propagated through the model to adjust the values of the variables. This process may be repeated for a plurality of samples at least until a determined loss or error is below a predefined threshold. In some examples, some of the training datasets 554 may be withheld and used to further validate or test the trained second machine learning model 566.

For unsupervised learning processes, the training datasets 554 may not include pre-assigned labels or scores to aid the learning process. Rather, unsupervised learning processes may include clustering, classification, or the like to identify naturally occurring patterns in the training datasets 554. K-means clustering or K-Nearest Neighbors may also be used, which may be supervised or unsupervised. Combinations of K-Nearest Neighbors and an unsupervised cluster technique may also be used. For semi-supervised learning, a combination of training datasets 554 with pre-assigned labels or scores and training datasets 554 without pre-assigned labels or scores may be used to train the model.

When reinforcement learning is employed, an agent (e.g., an algorithm) may be trained to make a decision regarding the metrics for the sample from the training datasets 554 through trial and error. For example, upon making a decision, the agent may then receive feedback (e.g., a positive reward if the predicted metrics were within a threshold value of the observed metrics), adjust its next decision to maximize the reward, and repeat until a loss function is optimized.

In some examples, a separate second machine learning model 566 may be trained for each architecture pattern (e.g., may be architecture pattern-specific). In such examples, the architecture pattern 558 need not be provided as input in the training process at step 564. These separate trained second machine learning models 566 may be stored in the trained model data store 120 in association with the type of architecture pattern they are trained to be specific to. Resultantly, the appropriate model can be retrieved for use during the deployment phase 568 (e.g., a model corresponding to the architecture pattern 520 determined by the first machine learning system 112 may be retrieved). In other examples, the trained second machine learning model 566 may be common across architecture patterns.

Once trained, the trained second machine learning model 566 may be stored (e.g., in the trained model data store 120) and subsequently applied by the second machine learning system 114 during the deployment phase 568. For example, during the deployment phase 568, the trained second machine learning model 566 executed by the second machine learning system 114 may receive input data 570. The input data 570 may include a use case 572 and an architecture pattern 574 for the application. In some examples, the use case 572 may be derived or otherwise identified or extracted from obtained conversation data between a user and a virtual assistant that is associated with the use case for the application. The architecture pattern 574 may be received from the first machine learning system 112. For example, the architecture pattern 574 may be the architecture pattern 520 that is output by the trained first machine learning model, described above with reference to FIG. 5A.

The second machine learning model 566 may provide, as output data, predicted optimization factor metrics 576 for various permutations or combinations of particular tools of respective tool types (e.g., derived from the lists stored in the tool data store 118) indicated by the architecture pattern 574 for serving the use case 572. In some examples, the permutation or combination of the particular tools of the respective tool types having the most beneficial predicted optimization factor metrics 576 for at least one driving optimization factor for the use case 572 (e.g., lowest cost, highest performance, etc.) may be the tools determined via a tool determination process (not shown).

During the monitoring phase 578, feedback associated with the output data of the trained second machine learning model 566 may be received and stored in the feedback data store 122. For example, actual optimization factor metrics 580 of the application observed when the architecture pattern 574 and the particular tool for each tool type determined are implemented for the application may be collected during the monitoring phase 578. During a monitoring process 582, the actual optimization factor metrics 580 may be analyzed along with the predicted optimization factor metrics 576 and the input data 570 to determine an accuracy of the trained second machine learning model 566. In some examples, based on the analysis, the process 550 may return to the training phase 552, where at step 564 values of one or more variables of the trained second machine learning model 566 may be adjusted to improve the accuracy of the trained second machine learning model 566. For example, the architecture pattern 574 may be used as a label (e.g., similar to the label 562) to create a new training dataset 554 for use in retraining the trained second machine learning model 566. In some examples, the trained second machine learning model 566 may be retrained after a predefined number of new training datasets 554 have been received.

The exemplary processes 500, 550 described above are provided merely as examples, and may include additional, fewer, different, or differently arranged aspects than depicted in FIG. 5A and/or FIG. 5B.

FIG. 6 depicts an exemplary notification 600. The notification 600 may be generated by the architecture assistant system 110 based on an architecture pattern and tools of respective tool types determined by the architecture assistant system 110 based on a use case for the application. The notification 600 may be provided to the user device 102 for display. In some examples, the notification 600 may be provided as a text message, an electronic mail communication, or a push notification (e.g., a push notification of the application 104 associated with the architecture assistant system 110), among other examples.

As shown, the notification 600 may include the determined architecture pattern 602, and a listing 604 of the particular tool for each tool type determined to perform a corresponding function of a plurality of functions to serve the use case for the application. The notification may also include selectable control elements 603 to solicit the user's response or feedback to at least the determined architecture pattern 602 (e.g., like, dislike, re-determine, etc.). In some examples, and as shown in FIG. 6, the notification 600 may further include an indication 606 of the at least one driving optimization factor used in the determination (e.g., cost). Additionally, the notification 600 may include an option 608 to select a different driving optimization factor (e.g., performance) by interacting with the notification 600 (e.g., by selecting a link in the notification 600).

The notification 600 described above is provided merely as an example, and may include additional, fewer, different, or differently arranged information and/or interactive control elements than depicted in FIG. 6.

In general, any process or operation discussed in this disclosure that is understood to be computer-implementable, such as the processes or operations depicted in FIGS. 2-6, may be performed by one or more processors of a computer system, such any of the systems or devices in the environment 100 of FIG. 1, as described above. A process or process step performed by one or more processors may also be referred to as an operation. The one or more processors may be configured to perform such processes by having access to instructions (e.g., software or computer-readable code) that, when executed by the one or more processors, cause the one or more processors to perform the processes. The instructions may be stored in a memory of the computer system. A processor may be a central processing unit (CPU), a graphics processing unit (GPU), or any suitable type of processing unit.

A computer system, such as a system or device implementing a process or operation in the examples above, may include one or more computing devices, such as one or more of the systems or devices in FIG. 1. One or more processors of a computer system may be included in a single computing device or distributed among a plurality of computing devices. A memory of the computer system may include the respective memory of each computing device of the plurality of computing devices.

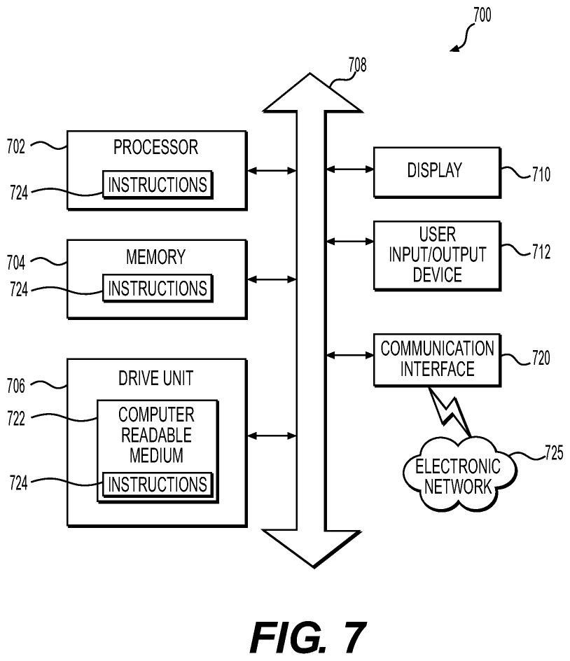

FIG. 7 depicts an example of a computer 700, according to certain embodiments. FIG. 7 is a simplified functional block diagram of a computer 700 that may be configured as a device for executing processes or operations depicted in, or described with respect to, FIGS. 2-6, according to exemplary embodiments of the present disclosure. For example, the computer 700 may be configured as the user device 102, one of the server-side systems 108, and/or another device according to exemplary embodiments of this disclosure. In various embodiments, any of the systems herein may be a computer 700 including, e.g., a data communication interface 720 for packet data communication. The computer 700 may communicate with one or more other computers 700 using the electronic network 725. The electronic network 725 may include a wired or wireless network similar to the network 106 depicted in FIG. 1.

The computer 700 also may include a central processing unit (“CPU”), in the form of one or more processors 702, for executing program instructions 724. The program instructions 724 may include instructions for running one or more applications, including the application 104 associated with the architecture assistant system 110 (e.g., if the computer 700 is the user device 102). The program instructions 724 may include instructions for running one or more operations of the server-side systems 108 (e.g., if the computer 700 is a server device or other similar computing device of one or more of the respective server-side systems 108). The computer 700 may include an internal communication bus 708, and a drive unit 706 (such as read-only memory (ROM), hard disk drive (HDD), solid-state disk drive (SDD), etc.) that may store data on a computer readable medium 722, although the computer 700 may receive programming and data via network communications. The computer 700 may also have a memory 704 (such as random access memory (RAM)) storing instructions 724 for executing techniques presented herein, although the instructions 724 may be stored temporarily or permanently within other modules of computer 700 (e.g., processor 702 and/or computer readable medium 722). The computer 700 also may include user input and output ports 712 and/or a display 710 to connect with input and output devices such as keyboards, mice, touchscreens, monitors, displays, etc. The various system functions may be implemented in a distributed fashion on a number of similar platforms, to distribute the processing load. Alternatively, the systems may be implemented by appropriate programming of one computer hardware platform.

Program aspects of the technology may be thought of as “products” or “articles of manufacture” typically in the form of executable code and/or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, e.g., may enable loading of the software from one computer or processor into another. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution.

While the disclosed methods, devices, and systems are described with exemplary reference to transmitting data, it should be appreciated that the disclosed embodiments may be applicable to any environment, such as a desktop or laptop computer, an automobile entertainment system, a home entertainment system, etc. Also, the disclosed embodiments may be applicable to any type of Internet protocol.

It should be understood that embodiments in this disclosure are exemplary only, and that other embodiments may include various combinations of features from other embodiments, as well as additional or fewer features. For example, while some of the embodiments above pertain to training and/or using one or more trained machine learning models to determine architecture patterns and/or tools for applications, any suitable activity may be used.

It should be appreciated that in the above description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

Thus, while certain embodiments have been described, those skilled in the art will recognize that other and further modifications may be made thereto without departing from the spirit of the invention, and it is intended to claim all such changes and modifications as falling within the scope of the invention. For example, functionality may be added or deleted from the block diagrams and operations may be interchanged among functional blocks. Steps may be added or deleted to methods described within the scope of the present invention.

The above disclosed subject matter is to be considered illustrative, and not restrictive, and the appended claims are intended to cover all such modifications, enhancements, and other implementations, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description. While various implementations of the disclosure have been described, it will be apparent to those of ordinary skill in the art that many more implementations are possible within the scope of the disclosure. Accordingly, the disclosure is not to be restricted except in light of the attached claims and their equivalents.

What is claimed is:

1. A method for determining use case-specific architecture patterns and tools for applications, the method comprising:
receiving, from a user device, conversation data between a user and a virtual assistant associated with a use case for an application, the conversation data indicating one or more optimization factors;
identifying a plurality of functions to serve the use case based on the conversation data;
determining, using a first machine learning system, an architecture pattern for the application based on the plurality of functions, wherein the architecture pattern indicates a plurality of tool types for performing the plurality of functions;
for each tool type of the plurality of tool types, determining, using a second machine learning system, a particular tool from a plurality of tools associated with the respective tool type to perform a corresponding function from the plurality of functions based on the one or more optimization factors; and
providing a notification to the user device for display, wherein the notification includes the architecture pattern, the particular tool for each tool type, and at least one driving optimization factor from the one or more optimization factors.

2. The method of claim 1, wherein the notification further includes an option to select a different driving optimization factor, and the method further comprises:
receiving, from the user device, a selection of the different driving optimization factor;
adjusting one or more particular tools determined for one or more of the plurality of tool types based on the different driving optimization factor; and
providing an updated notification based on the adjusting to the user device for display.

3. The method of claim 1, wherein when the architecture pattern and the particular tool for each tool type are implemented for the application, the method further comprises:
collecting feedback data associated with the at least one driving optimization factor; and
retraining at least the second machine learning system based on the feedback data.

4. The method of claim 3, wherein the feedback data associated with the at least one driving optimization factor is collected per function of the plurality of functions.

5. The method of claim 1, wherein the first machine learning system implements a bucketization algorithm.

6. The method of claim 1, wherein:
the second machine learning system includes a machine learning model trained based on a plurality of training datasets and a plurality of corresponding labels,
each training dataset of the plurality of training datasets includes an application use case, an architecture pattern, and a set of particular tools, and
each label of the plurality of corresponding labels indicates one or more observed metrics associated with one or more optimization factors.

7. The method of claim 1, further comprising:
maintaining a plurality of lists corresponding to the plurality of tool types, each of the plurality of lists including the plurality of tools associated with the respective tool type and pointing to a plurality of characteristics associated with each of the plurality of tools;
identifying one or more keywords associated with each of the plurality of functions based on the conversation data; and
referencing a respective list of the plurality of lists for each tool type to identify a subset of the plurality of tools associated with the respective tool type having one or more characteristics matching the one or more keywords, wherein the particular tool for each tool type is determined, using the second machine learning system, from the subset of the plurality of tools associated with the respective tool type.

8. The method of claim 7, wherein each list of the plurality of lists is a hash map, and wherein each tool of the plurality of tools included in each list is a key mapped to values representing the plurality of characteristics associated with the respective tool.

9. The method of claim 1, wherein the particular tool for each tool type is associated with a same service provider.

10. The method of claim 1, wherein the particular tool for at least one of the plurality of tool types is associated with a different service provider than the particular tool for one or more other of the plurality of tool types.

11. The method of claim 1, wherein the virtual assistant is one of a rule-based chatbot or an artificial intelligence-based chatbot.

12. A method for determining use case-specific architecture patterns and tools for applications, the method comprising:
maintaining a plurality of lists corresponding to a plurality of tool types, each of the plurality of lists including a plurality of tools associated with the respective tool type and pointing to a plurality of characteristics associated with each of the plurality of tools;
receiving, from a user device, conversation data between a user and a virtual assistant associated with a use case for an application;
identifying a plurality of functions to serve the use case and one or more keywords associated with each of the plurality of functions based on the conversation data;
determining, using a first machine learning system, an architecture pattern for the application based on the plurality of functions, wherein the architecture pattern indicates at least a subset of the plurality of tool types for performing the plurality of functions;
referencing at least a subset of the plurality of lists corresponding to the subset of the plurality of tool types to identify a subset of the plurality of tools for each tool type having one or more characteristics matching the one or more keywords;
determining, using a second machine learning system, a particular tool from the subset of the plurality of tools for each tool type to perform a corresponding function from the plurality of functions based on the conversation data; and
providing a notification to the user device for display, wherein the notification includes the architecture pattern and the particular tool for each tool type and the subset of the plurality of tools for each tool type.

13. The method of claim 12, wherein the conversation data indicates one or more optimization factors, and the particular tool is determined from the subset of the plurality of tools for each tool type based on the one or more optimization factors.

14. The method of claim 13, wherein the notification further includes at least one driving optimization factor from the one or more optimization factors and an option to select a different driving optimization factor, and the method further comprises:
receiving, from the user device, a selection of the different driving optimization factor;
adjusting one or more particular tools determined for one or more of the subset of the plurality of tool types based on the different driving optimization factor; and
providing an updated notification based on the adjusting to the user device for display.

15. The method of claim 14, wherein when the architecture pattern and the particular tool for each tool type are implemented for the application, the method further comprises:
collecting feedback data associated with the at least one driving optimization factor; and
retraining at least the second machine learning system based on the feedback data.

16. The method of claim 12, wherein the first machine learning system implements a bucketization algorithm.

17. The method of claim 12, wherein:
the second machine learning system includes a machine learning model trained based on a plurality of training datasets and a plurality of corresponding labels,
each training dataset of the plurality of training datasets includes an application use case, an architecture pattern, and a set of particular tools, and
each label of the plurality of corresponding labels indicates one or more observed metrics associated with one or more optimization factors.

18. The method of claim 12, wherein each list of the plurality of lists is a hash map, and wherein each tool of the plurality of tools included in each list is a key mapped to values representing the plurality of characteristics associated with the respective tool.

19. The method of claim 12, wherein maintaining the plurality of lists corresponding to the plurality of tool types comprises:
periodically scraping website data to identify new tools and modifications to characteristics associated with existing tools.

20. A method for determining use case-specific architecture patterns and tools for applications, the method comprising:
receiving, from a user device, conversation data between a user and a virtual assistant associated with a use case for an application;
identifying a plurality of functions to serve the use case based on the conversation data;
determining an architecture pattern for the application based on the plurality of functions, wherein the architecture pattern indicates a plurality of tool types for performing the plurality of functions;
for each tool type of the plurality of tool types, determining a particular tool from a plurality of tools associated with the respective tool type to perform a corresponding function from the plurality of functions based on the conversation data; and
providing the architecture pattern and the particular tool determined for each tool type to the user device for display.
